(19) United States
(12) Patent Application Publication
(10) Pub. No.: US 2021/0289678 A1
(43) Pub. Date: Sep. 16, 2021

(54) INTERCONNECT SUBSTRATE HAVING BUFFER MATERIAL AND CRACK STOPPER AND SEMICONDUCTOR ASSEMBLY USING THE SAME

(71) Applicant: BRIDGE SEMICONDUCTOR CORP., Taipei City (TW)

(72) Inventors: Charles W. C. LIN, Singapore (SG); Chia-Chung WANG, Hsinchu County (TW)

(21) Appl. No.: 17/334,033

(22) Filed: May 28, 2021

Related U.S. Application Data
(63) Continuation-in-part of application No. 16/279,696, filed on Feb. 19, 2019.
Application No. 16/279,696 is a continuation-in-part of application No. 16/411,949, filed on May 14, 2019.
Application No. 16/279,696 is a continuation-in-part of application No. 16/046,243, filed on Jul. 26, 2018, now abandoned.
Application No. 16/046,243 is a continuation-in-part of application No. 14/846,987, filed on Sep. 7, 2015, now Pat. No. 10,420,204.
Application No. 14/846,987 is a continuation-in-part of application No. 15/605,920, filed on May 25, 2017, now abandoned.
Application No. 15/605,920 is a continuation-in-part of application No. 15/642,253, filed on Jul. 5, 2017, now abandoned.
Application No. 15/642,253 is a continuation-in-part of application No. 15/785,426, filed on Oct. 16, 2017, now abandoned.
Application No. 15/785,426 is a continuation-in-part of application No. 15/881,119, filed on Jan. 26, 2018, now abandoned.
Application No. 15/881,119 is a continuation-in-part of application No. 15/908,838, filed on Mar. 1, 2018, now abandoned.
Application No. 15/908,838 is a continuation-in-part of application No. 15/976,307, filed on May 10, 2018, now abandoned.
Application No. 16/411,949 is a continuation-in-part of application No. 16/400,879, filed on May 1, 2019, now abandoned.
Application No. 16/046,243 is a continuation-in-part of application No. 14/846,987, filed on Sep. 7, 2015, now Pat. No. 10,420,204.
Application No. 14/846,987 is a continuation-in-part of application No. 15/080,427, filed on Mar. 24, 2016, now abandoned.
Application No. 15/080,427 is a continuation-in-part of application No. 15/605,920, filed on May 25, 2017, now abandoned.
Application No. 15/605,920 is a continuation-in-part of application No. 15/642,253, filed on Jul. 5, 2017, now abandoned.
Application No. 15/642,253 is a continuation-in-part of application No. 15/881,119, filed on Jan. 26, 2018, now abandoned.
Application No. 15/881,119 is a continuation-in-part of application No. 15/908,838, filed on Mar. 1, 2018, now abandoned.
Application No. 15/908,838 is a continuation-in-part of application No. 15/976,307, filed on May 10, 2018, now abandoned.
Application No. 14/846,987 is a continuation-in-part of application No. 14/621,332, filed on Feb. 12, 2015, now abandoned.
Application No. 15/080,427 is a continuation-in-part of application No. 14/621,332, filed on Feb. 12, 2015, now abandoned.
Application No. 14/621,332 is a continuation-in-part of application No. 14/846,987, filed on Sep. 7, 2015, now Pat. No. 10,420,204.
Application No. 15/605,920 is a continuation-in-part of application No. 14/621,332, filed on Feb. 12, 2015, now abandoned.
Application No. 14/621,332 is a continuation-in-part of application No. 14/846,987, filed on Sep. 7, 2015, now Pat. No. 10,420,204.
Application No. 15/642,253 is a continuation-in-part of application No. 14/621,332, filed on Feb. 12, 2015, now abandoned.
Application No. 14/621,332 is a continuation-in-part of application No. 14/846,987, filed on Sep. 7, 2015, now Pat. No. 10,420,204.
Application No. 15/785,426 is a continuation-in-part of application No. 15/642,253, filed on Jul. 5, 2017, now abandoned.
Application No. 15/642,253 is a continuation-in-part of application No. 15/642,256, filed on Jul. 5, 2017, now abandoned.
Application No. 15/881,119 is a continuation-in-part of application No. 15/605,920, filed on May 25, 2017, now abandoned.
Application No. 15/605,920 is a continuation-in-part of application No. 14/621,332, filed on Feb. 12, 2015, now abandoned.
Application No. 14/621,332 is a continuation-in-part of application No. 14/846,987, filed on Sep. 7, 2015, now Pat. No. 10,420,204.
Application No. 15/908,838 is a continuation-in-part of application No. 15/415,844, filed on Jan. 25, 2017, now abandoned.
Application No. 15/415,844 is a continuation-in-part of application No. 15/415,846, filed on Jan. 25, 2017, now abandoned.
Application No. 15/415,846 is a continuation-in-part of application No. 15/473,629, filed on Mar. 30, 2017, now Pat. No. 10,134,711.
Application No. 15/473,629 is a continuation-in-part of application No. 15/642,253, filed on Jul. 5, 2017, now abandoned.
Application No. 15/415,844 is a continuation-in-part of application No. 15/166,185, filed on May 26, 2016, now Pat. No. 10,121,768.
Application No. 15/415,846 is a continuation-in-part of application No. 15/166,185, filed on May 26, 2016, now Pat. No. 10,121,768.
Application No. 15/415,844 is a continuation-in-part of application No. 15/289,126, filed on Oct. 8, 2016, now abandoned.
Application No. 15/415,846 is a continuation-in-part of application No. 15/289,126, filed on Oct. 8, 2016, now abandoned.
Application No. 15/415,844 is a continuation-in-part of application No. 15/353,537, filed on Nov. 16, 2016, now Pat. No. 10,354,984.
Application No. 15/415,846 is a continuation-in-part of application No. 15/353,537, filed on Nov. 16, 2016, now Pat. No. 10,354,984.
Application No. 15/473,629 is a continuation-in-part of application No. 15/166,185, filed on May 26, 2016, now Pat. No. 10,121,768.
Application No. 15/166,185 is a continuation-in-part of application No. 15/289,126, filed on Oct. 8, 2016, now abandoned.
Application No. 15/289,126 is a continuation-in-part of application No. 15/353,537, filed on Nov. 16, 2016, now Pat. No. 10,354,984.
Application No. 15/353,537 is a continuation-in-part of application No. 15/415,844, filed on Jan. 25, 2017, now abandoned.
Application No. 15/415,844 is a continuation-in-part of application No. 15/415,846, filed on Jan. 25, 2017, now abandoned.
Application No. 15/415,846 is a continuation-in-part of application No. 15/462,536, filed on Mar. 17, 2017, now abandoned.
Application No. 15/289,126 is a continuation-in-part of application No. 15/166,185, filed on May 26, 2016, now Pat. No. 10,121,768.
Application No. 15/353,537 is a continuation-in-part of application No. 15/166,185, filed on May 26, 2016, now Pat. No. 10,121,768.
Application No. 15/166,185 is a continuation-in-part of application No. 15/289,126, filed on Oct. 8, 2016, now abandoned.
Application No. 15/462,536 is a continuation-in-part of application No. 15/166,185, filed on May 26, 2016, now Pat. No. 10,121,768.
Application No. 15/166,185 is a continuation-in-part of application No. 15/289,126, filed on Oct. 8, 2016, now abandoned.
Application No. 15/289,126 is a continuation-in-part of application No. 15/353,537, filed on Nov. 16, 2016, now Pat. No. 10,354,984.
Application No. 16/400,879 is a continuation-in-part of application No. 15/605,920, filed on May 25, 2017, now abandoned.
Application No. 15/605,920 is a continuation-in-part of application No. 15/881,119, filed on Jan. 26, 2018, now abandoned.
(60) Provisional application No. 61/949,652, filed on Mar. 7, 2014.
(60) Provisional application No. 62/166,771, filed on May 27, 2015.

(51) Int. Cl. H05K 13/00; H05K 1/02; H01L 21/48; H01L 23/498; H01L 21/56; H05K 13/04

(52) U.S. Cl. CPC H05K 13/00; H01L 23/3121; H01L 21/4857; H01L 23/49822; H01L 21/568; H01L 23/49838; H05K 13/0469; H05K 13/0486; H01L 2224/18; H01L 2224/16227; H05K 2201/0187; H05K 2203/025; H05K 2203/063; H05K 2201/10106; H05K 1/0204

(57) ABSTRACT

An interconnect substrate includes a lower-modulus buffer material disposed around a thermally conductive base and a higher-modulus crack stopper disposed over the buffer material. By the difference of the elastic modulus between the crack stopper and the buffer material, thermo-mechanical induced stress can be absorbed in the buffer material, and crack propagation would be arrested by the crack stopper to ensure reliability of a routing trace which is deposited on the crack stopper and electrically coupled to vertical connecting elements in the buffer material. Further, the crack stopper can have low dissipation factor to ensure a lower rate of energy loss which is beneficial to high frequency applications.

### CROSS REFERENCE TO RELATED APPLICATIONS

This application is a continuation-in-part of U.S. application Ser. No. 16/279,696 filed Feb. 19, 2019 and a continuation-in-part of U.S. application Ser. No. 16/411,949 filed May 14, 2019. The U.S. application Ser. No. 16/279,696 is a continuation-in-part of U.S. application Ser. No. 16/046,243 filed Jul. 26, 2018, a continuation-in-part of U.S. application Ser. No. 14/846,987 filed Sep. 7, 2015, a continuation-in-part of U.S. application Ser. No. 15/605,920 filed May 25, 2017, a continuation-in-part of U.S. application Ser. No. 15/642,253 filed Jul. 5, 2017, a continuation-in-part of U.S. application Ser. No. 15/785,426 filed Oct. 16, 2017, a continuation-in-part of U.S. application Ser. No. 15/881,119 filed Jan. 26, 2018, a continuation-in-part of U.S. application Ser. No. 15/908,838 filed Mar. 1, 2018, and a continuation-in-part of U.S. application Ser. No. 15/976,307 filed May 10, 2018. The U.S. application Ser. No. 16/411,949 is a continuation-in-part of U.S. application Ser. No. 16/400,879 filed May 1, 2019.

The U.S. application Ser. No. 16/046,243 is a continuation-in-part of U.S. application Ser. No. 14/846,987 filed Sep. 7, 2015, a continuation-in-part of U.S. application Ser. No. 15/080,427 filed Mar. 24, 2016, a continuation-in-part of U.S. application Ser. No. 15/605,920 filed May 25, 2017, a continuation-in-part of U.S. application Ser. No. 15/642,253 filed Jul. 5, 2017, a continuation-in-part of U.S. application Ser. No. 15/881,119 filed Jan. 26, 2018, a continuation-in-part of U.S. application Ser. No. 15/908,838 filed Mar. 1, 2018, and a continuation-in-part of U.S. application Ser. No. 15/976,307 filed May 10, 2018. The U.S. application Ser. No. 14/846,987 is a continuation-in-part of U.S. application Ser. No. 14/621,332 filed Feb. 12, 2015. The U.S. application Ser. No. 15/080,427 is a continuation-in-part of U.S. application Ser. No. 14/621,332 filed Feb. 12, 2015 and a continuation-in-part of U.S. application Ser. No. 14/846,987 filed Sep. 7, 2015. The U.S. application Ser. No. 15/605,920 is a continuation-in-part of U.S. application Ser. No. 14/621,332 filed Feb. 12, 2015 and a continuation-in-part of U.S. application Ser. No. 14/846,987 filed Sep. 7, 2015. The U.S. application Ser. No. 15/642,253 is a continuation-in-part of U.S. application Ser. No. 14/621,332 filed Feb. 12, 2015, and a continuation-in-part of U.S. application Ser. No. 14/846,987 filed Sep. 7, 2015. The U.S. application Ser. No. 15/785,426 is a continuation-in-part of U.S. application Ser. No. 15/642,253 filed Jul. 5, 2017 and a continuation-in-part of U.S. application Ser. No. 15/642,256 filed Jul. 5, 2017. The U.S. application Ser. No. 15/881,119 is a continuation-in-part of U.S. application Ser. No. 15/605,920 filed May 25, 2017, a continuation-in-part of U.S. application Ser. No. 14/621,332 filed Feb. 12, 2015 and a continuation-in-part of U.S. application Ser. No. 14/846,987 filed Sep. 7, 2015. The U.S. application Ser. No. 15/908,838 is a continuation-in-part of U.S. application Ser. No. 15/415,844 filed Jan. 25, 2017, a continuation-in-part of U.S. application Ser. No. 15/415,846 filed Jan. 25, 2017, a continuation-in-part of U.S. application Ser. No. 15/473,629 filed Mar. 30, 2017 and a continuation-in-part of U.S. application Ser. No. 15/642,253 filed Jul. 5, 2017. The U.S. application Ser. No. 15/976,307 is a division of pending U.S. patent application Ser. No. 14/621,332 filed Feb. 12, 2015.

The U.S. application Ser. No. 14/621,332 claims benefit of U.S. Provisional Application Ser. No. 61/949,652 filed Mar. 7, 2014. The U.S. application Ser. Nos. 15/415,844 and 15/415,846 are continuation-in-part of U.S. application Ser. No. 15/166,185 filed May 26, 2016, continuation-in-part of U.S. application Ser. No. 15/289,126 filed Oct. 8, 2016 and continuation-in-part of U.S. application Ser. No. 15/353,537 filed Nov. 16, 2016. The U.S. application Ser. No. 15/473,629 is a continuation-in-part of U.S. application Ser. No. 15/166,185 filed May 26, 2016, a continuation-in-part of U.S. application Ser. No. 15/289,126 filed Oct. 8, 2016, a continuation-in-part of U.S. application Ser. No. 15/353,537 filed Nov. 16, 2016, a continuation-in-part of U.S. application Ser. No. 15/415,844 filed Jan. 25, 2017, a continuation-in-part of U.S. application Ser. No. 15/415,846 filed Jan. 25, 2017 and a continuation-in-part of U.S. application Ser. No. 15/462,536 filed Mar. 17, 2017. The U.S. application Ser. No. 15/166,185 claims the priority benefit of U.S. Provisional application Ser. No. 62/166,771 filed May 27, 2015. The U.S. application Ser. No. 15/289,126 is a continuation-in-part of U.S. application Ser. No. 15/166,185 filed May 26, 2016. The U.S. application Ser. No. 15/353,537 is a continuation-in-part of U.S. application Ser. No. 15/166,185 filed May 26, 2016 and a continuation-in-part of U.S. application Ser. No. 15/289,126 filed Oct. 8, 2016. The U.S. application Ser. No. 15/462,536 is a continuation-in-part of U.S. application Ser. No. 15/166,185 filed May 26, 2016, a continuation-in-part of U.S. application Ser. No. 15/289,126 filed Oct. 8, 2016 and a continuation-in-part of U.S. application Ser. No. 15/353,537 filed Nov. 16, 2016. The U.S. application Ser. No. 16/400,879 is a continuation-in-part of U.S. application Ser. No. 15/605,920 filed May 25, 2017 and a continuation-in-part of U.S. application Ser. No. 15/881,119 filed Jan. 26, 2018. The entirety of each of said Applications is incorporated herein by reference.

### FIELD OF THE INVENTION

The present invention relates to an interconnect substrate and, more particularly, to an interconnect substrate having a crack stopper over a buffer material and a semiconductor assembly using the same.

### DESCRIPTION OF RELATED ART

High performance microprocessors and ASICs require high performance substrates for signal interconnection. However, the conventional resin laminate substrates is prone to crack under stringent operational requirements, and thus these substrates are unreliable for practical usage. In certain applications, ceramic material, such as alumina or aluminum nitride, is a popular material choice due to its desirable electrically insulative property, high mechanical strength, low CTE (coefficient of thermal expansion) and good thermal conductivity. Therefore, multi-layer ceramic substrates, including HTCC (high temperature co-fired ceramic) or LTCC (low temperature co-fired ceramic), have been developed for specific application requirements. However, multi-layer circuitry ceramic substrates are costly and at a higher risk of CTE fractures due to a large thermal mismatch between the ceramic material and the printed circuit board (PCB).

In view of the various development stages and limitations in current substrates, improving substrate's electrical, thermal and mechanical performances is highly desirable.

### SUMMARY OF THE INVENTION

An objective of the present invention is to provide an interconnect substrate with a lower-modulus buffer material disposed around a thermally conductive base and a higher-modulus crack stopper disposed over the buffer material. By the difference of the elastic modulus between the crack stopper and the buffer material, thermo-mechanical induced stress can be absorbed in the buffer material and crack propagation would be arrested by the crack stopper to ensure circuitry reliability on the crack stopper. As the buffer material can be CTE matched with a PCB, the risk of CTE fractures due to thermal mismatch between the interconnect substrate and the PCB can be reduced. Additionally, by use of a higher-modulus material with low dissipation factor (Df) in the crack stopper, a lower rate of energy loss can be achieved, thereby ensuring signal integrity.

In accordance with the foregoing and other objectives, the present invention provides an interconnect substrate, which includes: a thermally conductive base that has a top side and a bottom side; a plurality of vertical connecting elements that laterally surround a periphery of the thermally conductive base; a buffer material that fills in spaces between the vertical connecting elements and is attached to peripheral sidewalls of the thermally conductive base, wherein an elastic modulus of the buffer material is lower than that of the thermally conductive base by at least 50 GPa; a crack stopper that covers a top surface of the buffer material and has interior sidewalls around a cavity, wherein the top side of thermally conductive base is aligned with the cavity, and the crack stopper contains a higher-modulus material that has an elastic modulus of at least 300 GPa and has a dissipation factor (Df) of 0.005 or less; and a routing trace that is disposed over a top surface of the crack stopper and includes metallized vias that extend through the crack stopper and electrically connected to the vertical connecting elements.

The present invention also provides a semiconductor assembly, which includes: the aforementioned interconnect substrate; a semiconductor device that is disposed in the cavity and attached to the top side of the thermally conductive base; and bonding wires that provide electrical connection between the semiconductor device and the routing trace.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIG. 1 is a cross-sectional view of a thermally conductive base and vertical connecting elements disposed around the thermally conductive base in accordance with the first embodiment of the present invention;

FIG. 2 is a cross-sectional view of the structure of FIG. 1 further provided with a buffer material in accordance with the first embodiment of the present invention;

FIG. 3 is a cross-sectional view of the structure of FIG. 2 further provided with a crack stopper in accordance with the first embodiment of the present invention;

FIG. 4 is a cross-sectional view of the structure of FIG. 3 further formed with via openings in accordance with the first embodiment of the present invention;

FIG. 5 is a cross-sectional view of the structure of FIG. 4 further provided with a routing trace in accordance with the first embodiment of the present invention;

FIG. 6 is a cross-sectional view of the structure of FIG. 5 further formed with a cavity to finish the fabrication of an interconnect substrate in accordance with the first embodiment of the present invention;

FIG. 7 is a cross-sectional view of a semiconductor assembly with a semiconductor device mounted on the interconnect substrate of FIG. 6 in accordance with the first embodiment of the present invention;

FIG. 8 is a cross-sectional view of the structure having a thermally conductive base, vertical connecting elements and a buffer material in accordance with the second embodiment of the present invention;

FIG. 9 is a cross-sectional view of the structure of FIG. 8 further provided with a crack stopper and via openings in accordance with the second embodiment of the present invention;

FIG. 10 is a cross-sectional view of the structure of FIG. 9 further provided with a routing trace in accordance with the second embodiment of the present invention;

FIG. 11 is a cross-sectional view of the structure of FIG. 10 further formed with a cavity to finish the fabrication of another interconnect substrate in accordance with the second embodiment of the present invention; and

FIG. 12 is a cross-sectional view of a semiconductor assembly with a semiconductor device mounted on the interconnect substrate of FIG. 11 in accordance with the second embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the following description of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

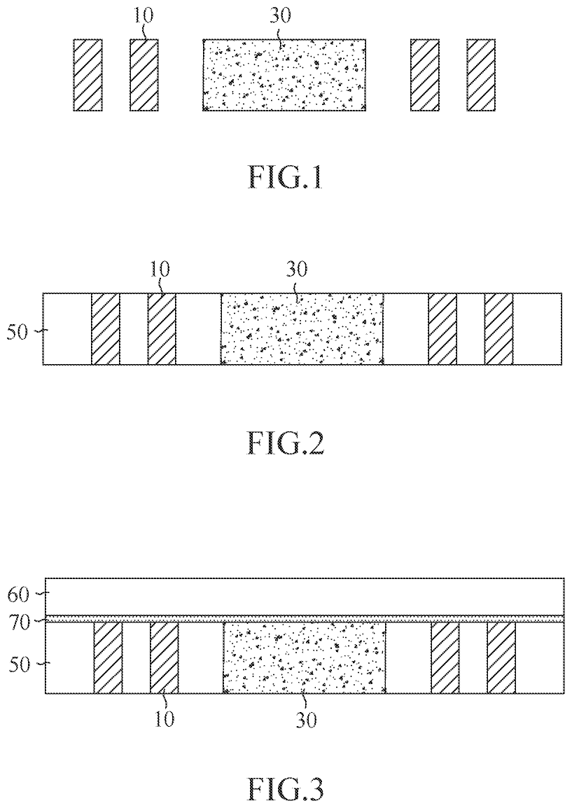

FIGS. 1-6 are cross-sectional views showing a method of making an interconnect substrate that includes a thermally conductive base, a plurality of vertical connecting elements, a buffer material, a crack stopper and a routing trace in accordance with the first embodiment of the present invention.

FIG. 1 is a cross-sectional view of the structure with vertical connecting elements 10 around a thermally conductive base 30. The vertical connecting elements 10 laterally surround the periphery of the thermally conductive base 30 and typically are made of copper. For effective heat dissipation, the thermally conductive base 30 preferably has a thermal conductivity higher than 10 W/mk. In this embodiment, the thermally conductive base 30 is made of a thermally conductive and electrically insulating inorganic material.

FIG. 2 is a cross-sectional view of the structure with a buffer material 50 dispensed in spaces between the vertical connecting elements 10 and is attached to peripheral sidewalls of the thermally conductive base 30. The buffer material 50 laterally covers and surrounds and conformally coats the peripheral sidewalls of the vertical connecting elements 10 and the thermally conductive base 30. The buffer material 50 provides a secure robust mechanical bond between the vertical connecting elements 10 and the thermally conductive base 30, and have top and bottom surfaces substantially coplanar with the top and bottom sides of the vertical connecting elements 10 and the thermally conductive base 30, respectively. Preferably, the buffer material 50 has an elastic modulus lower than that of the thermally conductive base 30 to absorb stress induced by any coefficient of thermal expansion (CTE) mismatch. For significant effect, the buffer material 50 may be an organic material having an elastic modulus lower than that of the thermally conductive base 30 by at least 50 GPa.

FIG. 3 is a cross-sectional view of the structure with a crack stopper 60 attached on top of the vertical connecting elements 10, the thermally conductive base 30 and the buffer material 50 using a binding material 70. The crack stopper 60 covers the vertical connecting elements 10, the thermally conductive base 30 and the buffer material 50 from above. To restrain propagation of cracks from the buffer material 50, the crack stopper 60 contains a higher-modulus material having an elastic modulus of at least 300 GPa and higher than that of the buffer material 50 by at least 200 GPa. By this difference of the elastic modulus, the stress can be absorbed in the buffer material 50 and crack propagation would be arrested by the crack stopper 60. Additionally, the higher-modulus material may have a CTE lower than that of the buffer material 50 by at least 5 ppm/° C. so as to enhance the effect of interrupting crack propagation. Further, in terms of signal integrity, the higher-modulus material preferably has a dissipation factor (Df) of 0.005 or less so that the crack stopper 60 ensures a lower rate of energy loss which is beneficial to high frequency applications. For significant effect, the amount of the higher-modulus material in the crack stopper 60 typically is higher than 20 percent by weight. In this embodiment, the crack stopper 60 contains an inorganic material having the aforementioned elastic modulus, CTE and Df properties at an amount of 100 wt % based on the total weight of the crack stopper 60. Accordingly, even if cracks are formed within the buffer material 50 or generated at interfaces between the thermally conductive base 30 and the buffer material 50 or between the vertical connecting element 10 and the buffer material 50 during thermal cycling, the crack stopper 60 can restrain the cracks from extending into the crack stopper 60 so as to ensure circuitry reliability on the crack stopper 60.

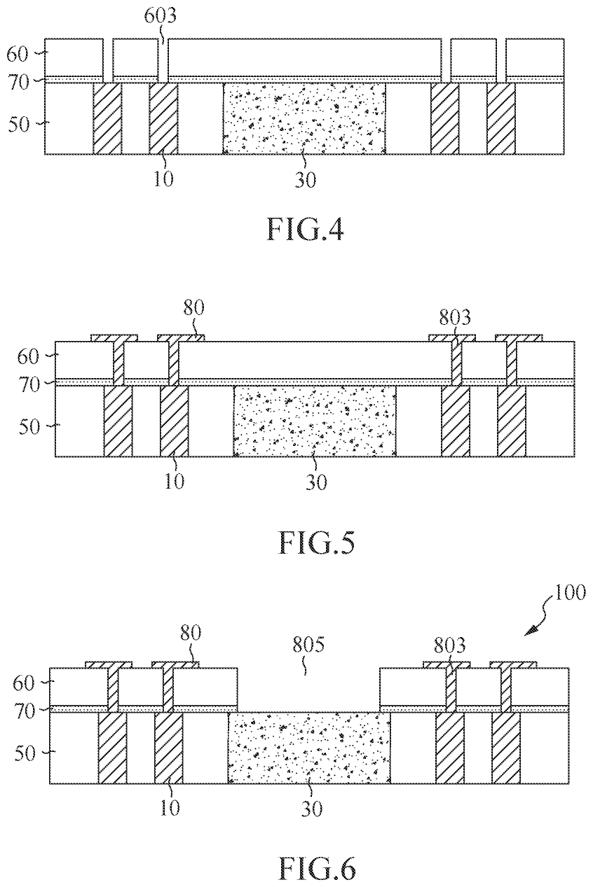

FIG. 4 is a cross-sectional view of the structure formed with via openings 603 through the crack stopper 60 and the binding material 70. The via openings 603 are formed by numerous techniques including laser drilling, plasma etching and photolithography. Laser drilling can be enhanced by a pulsed laser. Alternatively, a scanning laser beam with a metal mask can be used. The via openings 603 extend through the crack stopper 60 as well as the binding material 70, and are aligned with selected portions of the vertical connecting elements 10.

FIG. 5 is a cross-sectional view of the structure provided with a routing trace 80 on the crack stopper 60 by metal deposition and metal patterning process. The routing trace 80 typically is made of copper and extends from the top sides of the vertical connecting element 10 in the upward direction, fills up the via openings 603 to form metallized vias 803 in direct contact with the vertical connecting elements 10 and extends laterally on the top side of the crack stopper 60. As a result, the routing trace 80 can provide horizontal signal routing in both the X and Y directions and vertical routing through the via openings 603 and serve as electrical connections for the vertical connecting elements 10.

The routing trace 80 can be formed as a single layer or multiple layers by numerous techniques, such as electroplating, electroless plating, evaporating, sputtering or their combinations. For instance, the structure can be first dipped in an activator solution to render the crack stopper 60 catalytic to electroless copper, then a thin copper layer is electrolessly plated to serve as the seeding layer before a second copper layer is electroplated on the seeding layer to a desirable thickness. Alternatively, the seeding layer can be formed by sputtering a thin film such as titanium/copper onto the top surface of the structure before depositing the electroplated copper layer on the seeding layer. Once the desired thickness is achieved, the plated layer can be patterned to form the routing trace 80 by any of numerous techniques including wet etching, electro-chemical etching, laser-assist etching, and their combinations, with an etch mask (not shown) thereon that defines the routing trace 80.

FIG. 6 is a cross-sectional view of the structure formed with a cavity 605 to expose thermally conductive base 30 from above. The cavity 605 is aligned with the top side of thermally conductive base 30 and can formed by numerous techniques, such as punching, drilling or laser cutting. As a result, the crack stopper 60 and the binding material 70 have interior sidewalls around the cavity 605.

Accordingly, an interconnect substrate 100 is accomplished and includes the vertical connecting elements 10, the thermally conductive base 30, the buffer material 50, the crack stopper 60, the binding material 70 and the routing trace 80. The lower elastic modulus of the buffer material 50 helps in releasing thermo-mechanical induced stress and reducing stress accumulation. The crack stopper 60 covers the top surface of the buffer material 50 as well as interfaces between the thermally conductive base 30 and the buffer material 50 and between vertical connecting elements 10 and the buffer material 50 to restrain any crack formed within the buffer material 50 or generated at interfaces between heterogeneous material from propagating to the substrate surface and damage to the routing trace 80. Further, the crack stopper 60 can ensure signal integrity due to its low dissipation factor. Additionally, for next-level connection with a printed circuit board (not shown in the figure) from the bottom sides of the vertical connecting elements 10, the buffer material 50 preferably has CTE of 10 ppm/° C. or more to reduce CTE mismatch between the interconnect substrate 100 and the printed circuit board.

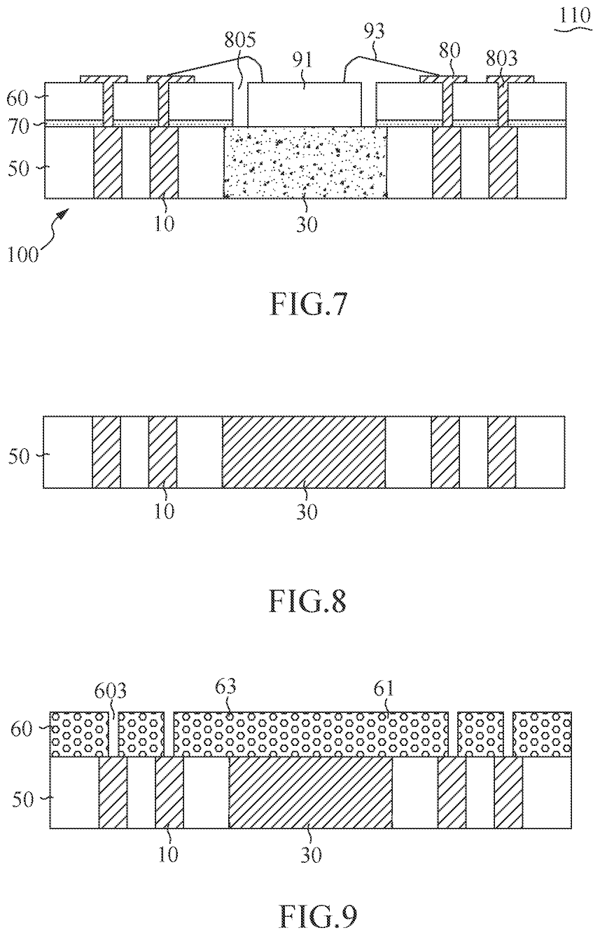

FIG. 7 is a cross-sectional view of a semiconductor assembly 110 with a semiconductor device 91 electrically connected to the interconnect substrate 100 illustrated in FIG. 6. The semiconductor device 91, illustrated as a chip, is disposed in the cavity 605 and attached to the top side of the thermally conductive base 30, and electrically connected to the routing trace 80 via bonding wires 93.

### Embodiment 2

FIGS. 8-11 are cross-sectional views showing a method of making another interconnect substrate in accordance with the second embodiment of the present invention.

For purposes of brevity, any description in Embodiment 1 is incorporated herein insofar as the same is applicable, and the same description need not be repeated.

FIG. 8 is a cross-sectional view of the structure similar to that illustrated in FIG. 2, except that the thermally conductive base 30 is made of a thermally and electrically conductive inorganic material.

FIG. 9 is a cross-sectional view of the structure provided with a crack stopper 60 from above and formed with via openings 603 in the crack stopper 60. In this embodiment, the crack stopper 60 includes a higher-modulus material 61 in an amount higher than 20 wt % (based on the total weight of the crack stopper 60) and a resin material 63 in a balance amount, and is directly attached to the top sides of the vertical connecting elements 10, the thermally conductive base 30 and the buffer material 50. As mentioned above, the higher-modulus material 61 dispersed in the crack stopper 60 has the elastic modulus of at least 300 GPa, which is higher than those of the buffer material 50 and the resin material 63, to interrupt crack propagation and suppress continuous cracks, and also has low dissipation factor of 0.005 or less to ensure signal integrity. The via openings 603 extend through the crack stopper 60 to expose selected portions of the vertical connecting elements 10 from above.

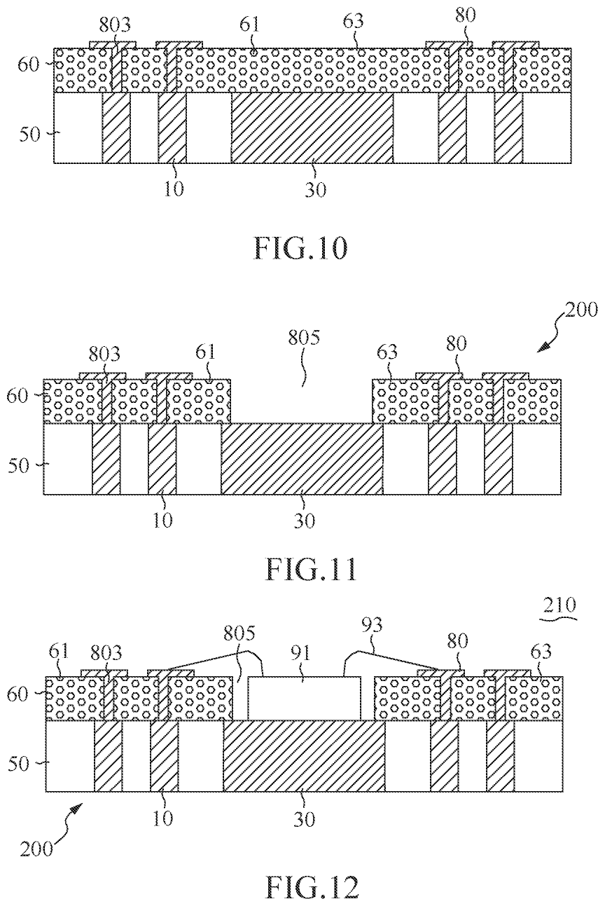

FIG. 10 is a cross-sectional view of the structure provided with a routing trace 80 in electrical connection with the vertical connecting elements 10. The routing trace 80 extends laterally on the top surface of the crack stopper 60 and includes metallized vias 803 penetrating through the crack stopper 60 to be direct contact with the vertical connecting elements 10.

FIG. 11 is a cross-sectional view of the structure formed with a cavity 605 to expose the thermally conductive base 30 from above. By the removal of the selected portion of the crack stopper 60, the cavity 605 is formed and allows a device to be displaced therein. Accordingly, an interconnect substrate 200 is accomplished and includes the vertical connecting elements 10, the thermally conductive base 30, the buffer material 50, the crack stopper 60 and the routing trace 80.

FIG. 12 is a cross-sectional view of a semiconductor assembly 210 with a semiconductor device 91 electrically coupled to the interconnect substrate 200 through bonding wires 93. The semiconductor device 91 is face-up disposed in the cavity 605 and electrically coupled to the routing circuitry 81 through the bonding wires 93.

As illustrated in the aforementioned embodiments, a distinctive interconnect substrate is configured to exhibit improved reliability. In a preferred embodiment, a buffer material is bonded to peripheral sidewalls of a thermally conductive base, and a crack stopper covers the top surface of the buffer material and allows a routing trace to be deposited thereon and electrically connected to vertical connecting elements laterally surrounded by the buffer material. The top side of the thermally conductive base and interior sidewalls of the crack stopper define a cavity for receiving a semiconductor device therein.

The thermally conductive base can provide primary heat conduction for the semiconductor device mounted thereon. The material of the thermally conductive base is not particularly limited as long as it can provide a locally high heat conduction channel. For example, the thermally conductive base may be made of a thermally conductive and electrically insulating inorganic material or a thermally and electrically conductive inorganic material.

The vertical connecting elements are spaced from the thermally conductive base by the buffer material, and have top sides electrically coupled to the routing circuitry and bottom sides for next-level connection with a PCB. In a preferred embodiment, the top and bottom sides of the vertical connecting elements are substantially coplanar with the top and bottom sides of the thermally conductive base as well as the top and bottom surfaces of the buffer material, respectively.

The buffer material laterally covers and surrounds and conformally coats the peripheral sidewalls of the thermally conductive base and the vertical connecting elements so as to provide secure robust mechanical bonds between the thermally conductive base and the vertical connecting elements. Preferably, the buffer material has an elastic modulus lower than those of the thermally conductive base, the vertical connecting elements and the crack stopper to absorb the stress induced by any coefficient of thermal expansion (CTE) mismatch between heterogeneous materials. For significant effect, the elastic modulus of the buffer material preferably is lower than that of the thermally conductive base by at least 50 GPa. Additionally, the buffer material preferably has CTE of 10 ppm/° C. or more to reduce CTE mismatch between the buffer material and a printed circuit board which is connected to the interconnect substrate from the bottom surface of the buffer material.

The crack stopper is attached on the top surface of the buffer material with or without a binding material between the crack stopper and the buffer material and laterally surrounds the cavity from which the top side of the thermally conductive base is exposed. The crack stopper contains a higher-modulus material to restrain propagation of cracks from the buffer material. More specifically, the elastic modulus of the higher-modulus material preferably is at least 300 GPa and higher than that of the buffer material by at least 200 GPa. Additionally, the higher-modulus material may have a CTE lower than the buffer material by at least 5 ppm/° C. so as to further enhance the effect of interrupting crack propagation. Further, in terms of signal integrity, the higher-modulus material preferably has a dissipation factor (Df) of 0.005 or less so that the crack stopper ensures a lower rate of energy loss which is beneficial to high frequency applications. For significant effect, the amount of the higher-modulus material in the crack stopper typically is higher than 20 percent by weight based on the total weight of the crack stopper. For instance, the crack stopper may be made of the higher-modulus inorganic material in 100 wt % or may further contain a resin material mixed with the higher-modulus inorganic material in an amount of higher than 20 wt % and lower than 100 wt %. In the aspect of the crack stopper having higher-modulus material in 100 wt %, the crack stopper is attached to the top surface of the buffer material by the binding material. As for another aspect of the crack stopper further including the resin material, the crack stopper can be directly attached to and contact the top surface of the buffer material.

The routing trace is a patterned metal layer laterally extending above the top surface of the crack stopper and spaced from the buffer material and the interfaces between heterogeneous materials by the crack stopper. By virtue of the crack stopper between the routing trace and the interfaces, the reliability of the routing trace can be ensured.

The present invention also provides a semiconductor assembly that includes a semiconductor device such as chip electrically connected to the aforementioned interconnect substrate using bonding wires. More specifically, the semiconductor device can be face-up mounted over the top side of the thermally conductive base and electrically coupled to the routing trace on the crack stopper using bonding wire(s) in contact with the routing trace and the semiconductor device.

The assembly can be a first-level or second-level single-chip or multi-chip device. For instance, the assembly can be a first-level package that contains a single chip or multiple chips. Alternatively, the assembly can be a second-level module that contains a single package or multiple packages, and each package can contain a single chip or multiple chips. The chip can be a packaged or unpackaged chip. Furthermore, the chip can be a bare chip, or a wafer level packaged die, etc.

The term “cover” refers to incomplete or complete coverage in a vertical and/or lateral direction. For instance, in a preferred embodiment, the crack stopper covers the buffer material regardless of whether another element such as the binding material is between the crack stopper and the buffer material.

The term “surround” refers to relative position between elements regardless of whether the elements are spaced from or adjacent to one another. For instance, in a preferred embodiment, the vertical connecting elements laterally surround the thermally conductive base and are spaced from the thermally conductive base by the buffer material.

The phrases “mounted on” and “attached on/to” include contact and non-contact with a single or multiple support element(s). For instance, in a preferred embodiment, the semiconductor device can be attached on the thermally conductive base regardless of whether it contacts the thermally conductive base or separated from the thermally conductive base by an adhesive.

The phrases “electrical connection”, “electrically connected” and “electrically coupled” refer to direct and indirect electrical connection. For instance, in a preferred embodiment, the semiconductor device is electrically connected to the routing trace by the bonding wires but does not contact the routing trace.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. An interconnect substrate, comprising:
a thermally conductive base that has a top side and a bottom side;
a plurality of vertical connecting elements that laterally surround a periphery of the thermally conductive base;
a buffer material that fills in spaces between the vertical connecting elements and is attached to peripheral sidewalls of the thermally conductive base, wherein an elastic modulus of the buffer material is lower than that of the thermally conductive base by at least 50 GPa;
a crack stopper that covers a top surface of the buffer material and has interior sidewalls around a cavity, wherein the top side of thermally conductive base is aligned with the cavity, and the crack stopper contains a higher-modulus material that has an elastic modulus of at least 300 GPa and has a dissipation factor (Df) of 0.005 or less; and
a routing trace that is disposed over a top surface of the crack stopper and includes metallized vias that extend through the crack stopper and electrically connected to the vertical connecting elements.

2. The interconnect substrate of claim 1, wherein the crack stopper further covers interfaces between the thermally conductive base and the buffer material.

3. The interconnect substrate of claim 1, further comprising a binding material that is disposed in between the crack stopper and the buffer material and between the crack stopper and the vertical connecting element and has interior sidewalls around the cavity.

4. The interconnect substrate of claim 1, wherein the amount of the higher-modulus material in the crack stopper is higher than 20 percent by weight.

5. The interconnect substrate of claim 1, wherein a coefficient of thermal expansion of the buffer material is higher than that of the crack stopper.

6. A semiconductor assembly, comprising:
the interconnect substrate of claim 1;
a semiconductor device that is disposed in the cavity and attached to the top side of the thermally conductive base; and
bonding wires that provide electrical connection between the semiconductor device and the routing trace.

7. The semiconductor assembly of claim 6, wherein crack stopper further covers interfaces between the thermally conductive base and the buffer material.

8. The semiconductor assembly of claim 6, wherein the interconnect substrate further comprises a binding material that is disposed in between the crack stopper and the buffer material and between the crack stopper and the vertical connecting element and has interior sidewalls around the cavity.

9. The semiconductor assembly of claim 6, wherein the amount of the higher-modulus material in the crack stopper is higher than 20 percent by weight.

10. The semiconductor assembly of claim 6, wherein a coefficient of thermal expansion of the buffer material is larger than that of the crack stopper.
